(19) United States
(12) Patent Application Publication
(10) Pub. No.: US 2025/0065364 A1
(43) Pub. Date: Feb. 27, 2025

(54) METHOD OF PRODUCING A WORKPIECE WITH A STRUCTURED LAYER

(71) Applicant: Hymmen GmbH Maschinen- und Anlagenbau, Bielefeld (DE)

(72) Inventor: René PANKOKE, Bielefeld (DE)

(73) Assignee: Hymmen GmbH Maschinen- und Anlagenbau, Bielefeld (DE)

(21) Appl. No.: 18/811,855

(22) Filed: Aug. 22, 2024

(30) Foreign Application Priority Data
Aug. 24, 2023 (DE) 10 2023 208 138.5

(51) Int. Cl. B05C 21/00; B05C 9/12; B05C 9/14; B05D 3/02; B05D 3/06; B05D 3/12

(52) U.S. Cl. CPC B05C 21/005; B05C 9/12; B05C 9/14; B05D 3/0254; B05D 3/06; B05D 3/12

(57) ABSTRACT

A method of manufacturing at least one workpiece having a structured layer on a support member (1) is disclosed. The method comprises the following steps:
step (S10): Providing the support member (1) having a liquid and curable layer (2) on a support member surface (7);
step (S12): applying a masking agent (3) onto the layer (2) such that the masking agent (3) has a first layer thickness at a first location (4) on the layer (2) and that the masking agent (3) has a second layer thickness at a second location (5) on the layer (2), wherein the first layer thickness is greater than the second layer thickness;
step (S14): curing the layer (2), wherein material of the layer (2) at the first location (4) below the masking agent (3) applied at the first location does not cure or cures less than material of the layer (2) at the second location (5) below the masking agent (3) applied at the second location; and
step (S16): Removing uncured material of the layer (2) so that the cured material of the layer (2) forms the structured layer having a height profile on the support member (1).

Furthermore, a device for carrying out the method is disclosed.

### RELATED APPLICATION

This application claims the benefit of priority of German Patent Application No. 10 2023 208 138.5 filed on Aug. 24, 2023, the contents of which are incorporated by reference as if fully set forth herein in their entirety.

### FIELD AND BACKGROUND OF THE INVENTION

The present invention relates to a method for producing at least one workpiece with a structured layer on a support member, and to a device for carrying out the method.

The production of workpieces with structured layers, in particular for decorative purposes, is known. For example, components for flooring or furniture production are provided with a wooden decor which, in addition to the wood look, also has haptically perceptible wood structures. Various approaches have been developed for this in the past. For example, a wood structure is embossed into a plastic layer using an embossing tool (e.g. embossing roller or embossing plate) in order to obtain the wood-typical indentations in the layer. The use of an embossing tool is generally not very flexible, as the design of the structure is limited to the pattern on the embossing tool.

Workpieces with structured layers are also further processed in subsequent production steps. For example, the edges of the layer, which are later available in particular as visible edges, are provided with a chamfer or rounding. This involves removing material, in particular material from the structured layer. This is time-consuming, as it involves at least one additional process step.

It is therefore an object of the present invention to provide an alternative to the above-mentioned methods in order to solve at least one of the above-mentioned problems.

This object is solved by the subject-matters of the independent claims. Advantageous further embodiments are subject matter of the dependent claims.

Preferably, a method for producing at least one workpiece with a structured layer on a support member is provided. The method has the following steps:
step S10: providing the support member having a liquid and curable layer on a support member surface;
step S12: applying a masking agent onto the layer such that the masking agent has a first layer thickness at a first location on the layer and such that the masking agent has a second layer thickness at a second location on the layer, wherein the first layer thickness is greater than the second layer thickness;
step S14: curing the layer, wherein material of the layer at the first location below the masking agent applied thereto does not cure or cures less than material of the layer at the second location below the masking agent applied thereto; and
step S16: removing uncured material of the layer so that the cured material of the layer forms the structured layer having a height profile on the support member.

Preferably, the workpiece or support member is plate-shaped.

Preferably, the structured layer thus forms a surface on the support member, which is characterized by a height profile. This means that the layer thickness of the layer on the support member changes at least along one direction in a sectional view through the workpiece produced in this way, whereby the cut is guided in such a way that both the support member and the layer are cut.

The masking agent protects the layer or the material of the layer under the masking agent from curing completely during the curing process. It is also conceivable that a complete blocking of the curing takes place at the first location and the layer remains liquid or at least in the state which it had before step S14.

Preferably, the height profile has a lower height at the first location than at the second location. In this way, it is possible to form structures in the layer that are for example modeled on any decors, such as wood, stone or tile decors. In general, a lower height means that less material of the layer has been cured at the first location, so that this has been removed after step S16 and a corresponding depression remains in the layer, i.e. a lower height of the height profile is created than at the second location.

Preferably, the first location and the second location are directly adjacent to each other. If the masking agent is applied in different layer thicknesses onto directly adjacent locations, it can be achieved during curing in step S14 that the adjacent locations cure to different degrees. Depending on the amount of masking agent applied onto these two locations and possibly other adjacent locations, a gradual curing of the material of the layer below may be achieved. If a correspondingly fine gradation of the amount of masking agent applied is carried out between the individual locations, a continuously variable curing of the layer from location to location may also be achieved. If, for example, the layer thickness of masking agent is greatest at the first location and is lower at the second location and decreases further at more adjacent locations, the layer below may be cured more and more, starting with the lowest curing at the first location. Removing uncured material from the layer then leads to a correspondingly gradual height profile.

Preferably, the first location or the second location is at an edge of the layer. In this way, the height profile may also be influenced at the edge of the layer. If the first location is at the edge of the layer and the second location is adjacent to the first location, starting from the edge of the layer towards the center of the layer, a curing of the layer that rises from the edge may be achieved and ultimately, after removal of the uncured material of the layer, a height profile that rises from the edge towards the center of the layer.

Preferably, the first location and the second location extend along a first direction parallel to the support member surface. In this way, it may be achieved that the height profile, which is created after the uncured material of the layer has been removed, extends along this direction. For example, if a depression has been formed at the first location or at the second location by removing the uncured material of the layer, it extends along this direction. For example, a height profile may be oriented to other contours of the workpiece. For example, the direction may run parallel to the edge of the layer or the support member.

Preferably, a separating tool is used to separate the support member with the layer thereon along the first direction. Particularly when manufacturing large quantities of such workpieces, it may be intended that a large support member with the layer thereon is cut into smaller formats. For this purpose, for example, a saw is used as a separating tool to cut through the support member and the layer thereon in order to obtain the desired format. The cut is preferably carried out after curing of the layer according to step S14. However, it may be carried out before or after the removal of uncured material of the layer according to step S16.

Preferably, the height profile is formed as a chamfer or rounding. The chamfer or rounding preferably runs along an edge of the layer or the support member. In this way, an additional processing step in which a chamfer or rounding is introduced by means of a tool may be omitted, because the chamfer or rounding is already formed as a height profile or part of the height profile with the removal of uncured material of the layer according to step S16.

The following method is preferred. A cutting direction or cutting line is defined as the first direction described above, along which a tool separates the workpiece and the layer thereon. Masking material is applied onto the layer parallel to this direction, so that the first location and the second location and possibly the other locations onto which masking material is applied onto the layer extend parallel to the direction, with the first location preferably being directly adjacent to the area through which the tool is guided when carrying out the cut. This may, for example, be the area onto the layer through which a saw blade is guided as a tool. After the layer has cured, the material of the layer below the masking material is correspondingly less cured. The cut may then be carried out to separate the workpiece, followed by the removal of uncured material from the layer (step S16). Alternatively, the uncured material of the layer may be removed first (step S16) and then the cut for separating the workpiece may be carried out. After removing uncured material from the layer, a height profile remains adjacent to the cutting edge, which, if the masking has been carried out accordingly at the first and second locations, is formed in particular as a chamfer or rounding parallel to the cutting edge. Subsequent formation of the chamfer or rounding in a separate processing step is therefore not necessary.

Preferably, the height profile has different heights along a second direction, which is perpendicular to the first direction and which runs parallel to the support member surface. The cross-section of the workpiece, which is determined by the height profile, thus changes in height along this second direction. Preferably, the cross-section does not change in the first direction. In this way, recesses or a height profile may be formed in the layer that correspond to milled grooves, chamfers or edge roundings or similar elements. However, it is not necessary to actually introduce grooves in a post-processing step.

Preferably, the height profile rises along the second direction, starting from a cutting edge produced by the separating tool. In this way, a height profile is generated starting from the cutting edge, which may be formed as a chamfer, rounding or the like. In this way, mechanical post-processing of the edges of the workpiece may be omitted.

Preferably, the masking agent is applied onto partial areas of the layer, whereby at least a third location of the layer remains uncovered by the masking agent. This location is then exposed and is not prevented from curing during curing (step S14). Preferably, this location cures such that no material is removed from this location during the removal of uncured material of the layer (step S16).

Preferably, the masking agent is applied onto the layer in step S12 in liquid form. In this way, dosing is easily possible.

Preferably, the masking agent is applied onto the layer in step S12 as droplets, particularly preferably using a digital printing device. A digital printing device enables the flexible and precise application of the masking agent, whereby it is also possible to dose the masking agent accordingly.

Preferably, the layer is partially dried or cured prior to step S12 to enable the masking agent to be carried by the layer. Drying may, for example, be carried out by applying heat to the layer so that liquid is removed from the layer, for example by evaporation, so that its viscosity, surface tension and/or density is changed accordingly in order to be able to support the masking agent. Curing to change the viscosity, surface tension and/or density accordingly may be carried out in the same way as the curing according to step S14, as described in particular below. However, in each case, the drying or curing prior to step S12 is carried out such that the layer is not completely cured so that removal of material from the layer is still possible in step S16.

Preferably, the curing in step S14 comprises curing by radiation, application of heat and/or drying. The layer is preferably in the form of a polymerizable layer that can be polymerized by radiation from a curing device. In particular, UV radiation, IR radiation or electron radiation may be used for this purpose. When heat is applied, for example, a solvent or liquid in the layer may evaporate and/or liquid is removed from the layer during drying.

The masking agent is preferably a digital or analog printable ink that is solvent-based or water-based. Alternatively, the masking agent may also be water.

Preferably, the uncured material of the layer in step S16 is removed mechanically and/or contactlessly. In the case of mechanical removal, this may be carried out by a contact element. In particular, the contact element may comprise a brush element, such as a stationary or rotating brush, and/or a plane element, which removes uncured material of the layer when in contact with the layer. In the case of contactless removal, particularly a fluid flow from a nozzle may be used, which is directed onto the layer and removes uncured material of the layer. The fluid flow may preferably contain solids such as sand, dry ice or the like. Removed material of the layer is preferably sucked up by means of a suction device. The suction device is preferably positioned in such a way that the material of the layer removed by means of the contact element or fluid flow is moved towards the suction device. The contact element, nozzle and/or suction device may be part of a removal device of the device described further below.

Preferably, step S10 comprises applying the layer onto the support member. The layer may be applied by means of a digital printing device or by another method. In particular, the layer may be applied by means of an analog printing process in which a printing roller or a casting device is used.

Alternatively or additionally, step S10 comprises that a base decor is located or applied below the layer, wherein the base decor is visible through the structured layer. The base decor may usually be a decorative image. If, for example, a wooden decor is to be created, a wooden decor is present on the workpiece as the base decor or is applied to it. A digital or analog printing device may be used for the application. The structured layer itself, i.e. the cured layer on the support member that is provided with the height profile, is preferably configured such that it is at least partially transparent, so that the base decor can be recognized and the structured layer in conjunction with the visible base decor form an optical entity for an observer.

A device for carrying out the method described above is described below. It is clear to a person skilled in the art that the embodiments of the method described above are also to be understood as corresponding structural features of the device.

Preferably, a device is provided for carrying out the method described above. The apparatus comprises the following elements:
an application device configured to apply the masking agent onto the layer;
a curing device configured for curing the layer; and
a removal device configured to remove uncured material of the layer, wherein the device comprises a control device configured to control the application device, the curing device and the removal device according to steps S12, S14 and S16.

Preferably, the device comprises at least one of the following elements:
a preparation device configured to provide the support member and, in particular, to perform step S10 as described above; and/or
a separating device comprising a separating tool and configured to perform a separation of the support member with the layer thereon along the first direction.

Preferably, the device has a transport device, particularly preferably with a belt conveyor, which is configured to transport the support member or the workpiece to the respective elements.

The invention is described below with reference to preferred embodiments with the aid of the accompanying drawings.

### BRIEF DESCRIPTION OF THE SEVERAL VIEWS OF THE DRAWINGS

FIG. 1 a flow chart of a preferred embodiment of the method of the method,

FIG. 2a-c production phases of a workpiece according to a first embodiment of the method,

FIG. 3a-c production phases of a workpiece according to a second embodiment of the method, and

FIG. 4a-c manufacturing phases of a workpiece according to a third embodiment.

### DESCRIPTION OF SPECIFIC EMBODIMENTS OF THE INVENTION

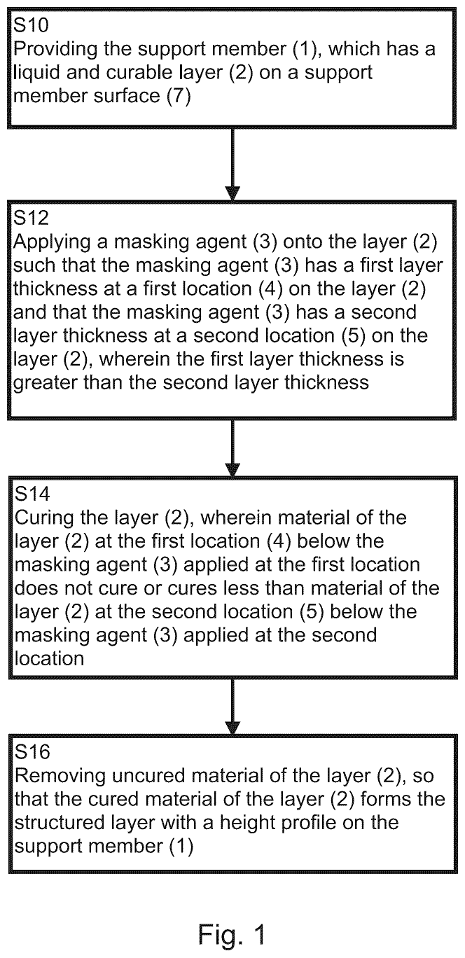

FIG. 1 shows a flow chart of a preferred embodiment of the method.

The method shown is used for producing at least one workpiece with a structured layer on a support member and has the following steps:
step S10: providing the support member having a liquid and curable layer on a support member surface;
step S12: applying a masking agent onto the layer such that the masking agent has a first layer thickness at a first location on the layer and such that the masking agent has a second layer thickness at at least a second location on the layer, wherein the first layer thickness is greater than the second layer thickness;
step S14: curing the layer, wherein material of the layer at the first location below the masking agent applied thereto does not cure or cures less than material of the layer at the second location below the masking agent applied thereto; and
step S16: removing uncured material of the layer so that the cured material of the layer forms the structured layer having a height profile on the support member.

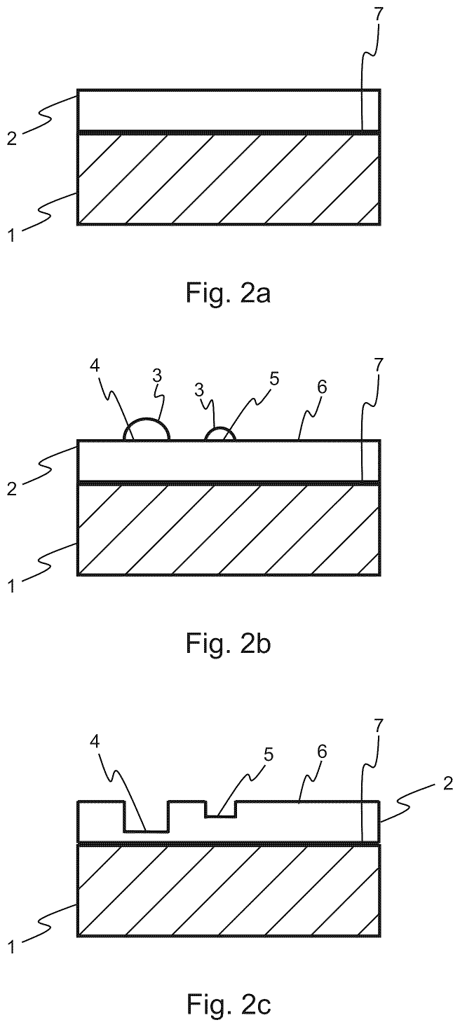

The production phases of a workpiece according to FIGS. 2a-c, 3a-c and 4a-c described below refer to the method steps described above.

FIGS. 2a-c show production phases of a workpiece according to a first embodiment of the method.

In FIG. 2a, a workpiece is shown in section, which has a support member 1 and a layer 2 on a support member surface 7. A base decor, such as a decorative image, may be present on the support member surface 7. The state of the workpiece shown here corresponds to the state at the end of step S10, as explained in FIG. 1 and in the general description.

In FIG. 2b, the workpiece is shown with a masking agent 3 now applied onto the layer 2 at a first location 4 and at a second location 5. The masking agent 3 was applied in such a way that a first layer thickness of the masking agent 3 at the first location 4 is greater than a layer thickness of the masking agent 3 at the second location 5. A third location 6 of the layer 2 has not been covered with the masking agent 3. That location is exposed. The state shown in FIG. 2b corresponds to the state after the execution of step S12.

The masking agent 3 is configured to attenuate the effect of the curing on the material of the layer 2 below the masking agent 3 at the first location 4 and at the second location 5 during the subsequent curing of the layer according to step S14, or to block it completely at the first location 4 if the layer thickness of the masking agent 3 is selected accordingly. The curing according to step S14 is then carried out, for example, by radiation, such as UV radiation, IR radiation or electron radiation, from a curing device, whereby the layer 2 cures the most at location 6 and the least at location 4. The masking agent 3 acts here as a blocking for the radiation input or at least attenuates the radiation input.

FIG. 2c then shows the state of the workpiece after step S16 has been carried out and the uncured material of layer 2 has been removed. The removal may, as described above, be carried out in particular mechanically and/or contactlessly. At the first location 4, greater shielding of the layer 2 was achieved by the masking agent 3 applied with greater layer thickness, so that only slight curing took place here and a relatively large amount of material could be removed. In comparison, a lesser shielding of the layer 2 was achieved at the second location 5 and thus its curing was not prevented to the same extent, so that less uncured material was present here, which was removed. The exposed third location 6 of layer 2, on the other hand, is completely cured, so that no uncured material was present here and therefore could not be removed. This can be explained by the fact that after curing S14, layer 2 is adapted for removal according to step S16 in such a way that cured material of layer 2 is not removed. As a result, indentations are thus present at locations 4 and 5, with the first location 4 having the larger indentation, as more uncured material was removed here.

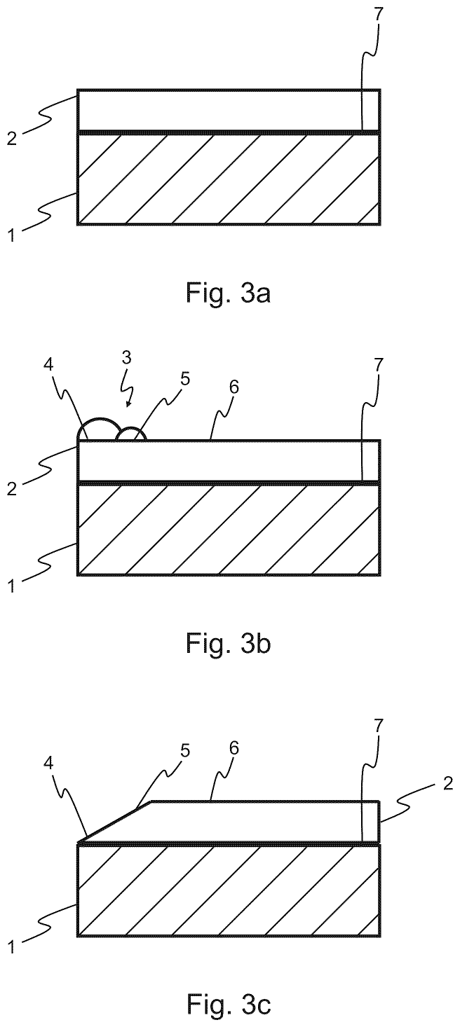

FIGS. 3a-c show production phases of a workpiece according to a second embodiment of the method.

In FIG. 3a, a workpiece is shown in section, which has a support member 1 and a layer 2 on a support member surface 7. A base decor, such as a decorative image, may be present on the support member surface 7. The state of the workpiece shown here corresponds to the state at the end of step S10, as explained in FIG. 1 and in the general description.

Essentially the same states are shown here as in FIGS. 2a-c. In contrast, however, step S12, namely the application of the masking agent 3, was carried out in such a way that the first location 4 is now adjacent to the left edge of the layer 2 and the second location 5 is adjacent to the right of the first location 4. This is shown in FIG. 3b. Thereby it is achieved that the material of the layer 2 below the masking agent 3 at the first location 4 cures to a lesser extent than the material of the layer 2 below the masking agent 3 at the second location 5. At the locations 4 and 5, there is a steadily increasing effect of the curing S14 from left to right until finally the entire layer 2 cures according to the exposed third location 6.

If the uncured material of layer 2 is now removed according to step S16, a height profile remains that rises from left to right up to the maximum height of layer 2 in the section shown in FIG. 3c. If the masking agent 3 is applied in such a way that the locations 4 and 5 extend parallel to the edge or border of the layer 2, i.e. perpendicular to the drawing plane in the drawing in FIG. 3b, the left edge of the layer 2 and thus the respective edge of the workpiece may be provided with a chamfer here.

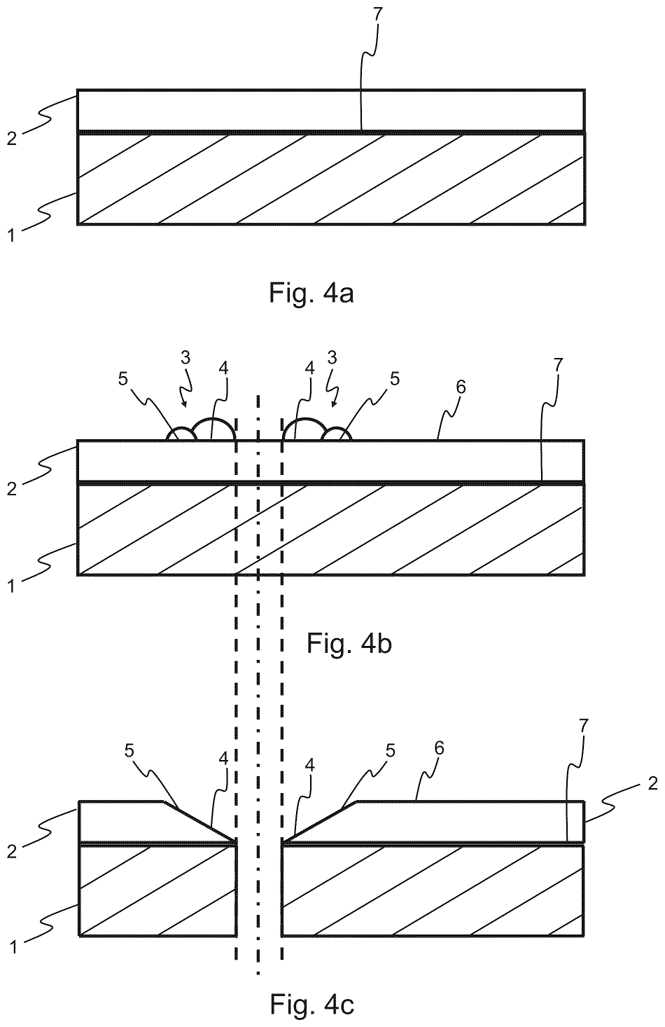

FIGS. 4a-c show production phases of a workpiece according to a third embodiment of the process.

In FIG. 4a, a workpiece is shown in section, which has a support member 1 and a layer 2 on a support member surface 7. A base decor, such as a decorative image, may be present on the support member surface 7. The state of the workpiece shown here corresponds to the state at the end of step S10, as explained in FIG. 1 and in the general description.

As shown in FIG. 4b, the masking agent in step S12 was not applied to the edge of layer 2, as shown in FIG. 3b. Instead, the masking agent 3 was applied here in accordance with step S12, so that a first location 4 is present which has a greater layer thickness of masking agent 3 than an adjacent second location 5. In addition, the application was carried out in such a way that a further configuration with a first location 4 and a second location 5 is present on the workpiece. The arrangement of the first and second locations 4, 5 was mirrored at the dot-dashed line drawn vertically in the drawing, so that the area marked by the two dotted vertical lines is present between the two configurations of the first and second locations 4, 5. This area represents the area in which a separating tool is subsequently guided. The respective first locations 4 are directly adjacent to this area. The locations 4 and 5 extend perpendicular to the drawing plane and thus parallel to the first direction in which the separating tool is guided.

FIG. 4c then shows the state after the curing of layer 2 according to step S14 and the removal of uncured material of layer 2 according to step S16. In addition, a separating tool, such as a saw, was used to separate the workpiece, so that both the material of the support member 1 and the material of layer 2, which were located in the area indicated by the dashed lines, were removed. Two separate workpieces can now be seen to the right and left of this area.

By allocating the layer thicknesses of masking agent 3 at locations 4 and 5 accordingly, the material of layer 2 underneath is prevented from curing, whereby after step S16 a height profile corresponding to the chamfers shown is formed on layer 2 adjacent to the area indicated by the dashed lines.

As a result, a further processing step for subsequent generation of the chamfers may be omitted, as they have already been generated as a height profile. The generated chamfers run from the respective cutting edge, i.e. the area marked by the dotted lines, to the left or right in a second direction, increasing in height. The second direction extends in the drawing plane perpendicular to the first direction and parallel to the support member surface 7.

### LIST OF REFERENCE SIGNS

1 support member
2 layer
3 masking agent
4 first location of the layer
5 second location of the layer
6 third location of the layer
7 support member surface
S10, S12, S14, S16: method steps

What is claimed is:

1. Method for producing at least one workpiece with a structured layer on a support member (1), comprising the steps:
step (S10): providing the support member (1), which has a liquid and curable layer (2) on a support member surface (7);
step (S12): applying a masking agent (3) onto the layer (2) such that the masking agent (3) has a first layer thickness at a first location (4) on the layer (2) and that the masking agent (3) has a second layer thickness at a second location (5) on the layer (2), wherein the first layer thickness is greater than the second layer thickness;
step (S14): curing the layer (2), wherein material of the layer (2) at the first location (4) below the masking agent (3) applied at the first location does not cure or cures less than material of the layer (2) at the second location (5) below the masking agent (3) applied at the second location; and
step (S16): removing uncured material of the layer (2), so that the cured material of the layer (2) forms the structured layer with a height profile on the support member (1).

2. Method according to claim 1, wherein
the height profile at the first location (4) has a lower height than at the second location (5).

3. Method according to claim 1, wherein
the first location (4) and the second location (5) are directly adjacent to each other.

4. Method according to claim 1, wherein
the first location (4) or the second location (5) is located at an edge of the layer (2).

5. Method according to claim 1, wherein
the first location (4) and the second location (5) extend along a first direction parallel to the support member surface (7).

6. Method according to claim 5, wherein
separating the support member (1) with the layer (2) thereon along the first direction is carried out by a separating tool.

7. Method according to claim 1, wherein
the height profile is shaped as a chamfer or rounding.

8. Method according to claim 5, wherein
the height profile has different heights along a second direction which is perpendicular to the first direction and which runs parallel to the support member surface (7).

9. Method according to claim 6, wherein
the height profile has different heights along a second direction which is perpendicular to the first direction and which runs parallel to the support member surface (7), the height profile rises along the second direction, starting from a cutting edge produced by the separating tool.

10. Method according to claim 1, wherein
the masking agent (3) is applied onto partial areas of the layer (2) and at least a third location (6) of the layer (2) remains uncovered by the masking agent (3).

11. Method according to claim 1, wherein
the masking agent (3) is applied onto the layer (2) in liquid form in step (S12).

12. Method according to claim 1, wherein
the masking agent (3) is applied as droplets onto the layer (2) using a digital printing device in step (S12).

13. Method according to claim 1, wherein
the layer (2) is partially dried or cured before step (S12) to allow the masking agent (3) to be carried by the layer (2).

14. Method according to claim 1, wherein
the curing in step (S14) comprises curing by radiation, application of heat and/or drying.

15. Method according to claim 1, wherein
the removal of uncured material of the layer (2) in step (S16) is carried out mechanically and/or or in a contactless manner.

16. Method according to claim 1, wherein
step (S10) comprises that the layer (2) is applied onto the support member (1) and/or that a base decor is located or applied below the layer (2), wherein the base decor is visible through the structured layer.

17. Device for carrying out the method according to claim 1, comprising the following elements:
an application device configured to apply the masking agent (3) onto the layer (2);
a curing device configured to cure the layer (2); and
a removal device configured to remove uncured material of the layer (2), wherein
the device comprises a control device configured to control the application device, the curing device and the removal device according to steps (S12, S14, S16).

18. Device according to claim 17, comprising at least one of the following elements:
a preparation device configured to provide the support member (1); and/or
a separating device comprising a separating tool and configured to perform a separation of the support member (1) with the layer (2) thereon along the first direction.
